(19) United States
(12) Patent Application Publication
(10) Pub. No.: US 2025/0323195 A1
(43) Pub. Date: Oct. 16, 2025

(54) MEMORY CHIPLET BOND PAD CONFIGURATION

(71) Applicant: Western Digital Technologies, Inc., San Jose, CA (US)

(72) Inventors: Chengqing Hu, Milpitas, CA (US); Henry Chin, Fremont, CA (US); Jun Tao, Santa Clara, CA (US); Deepanshu Dutta, Fremont, CA (US); Zhixin Cui, Fremont, CA (US); Xiang Yang, Santa Clara, CA (US)

(73) Assignee: Western Digital Technologies, Inc., San Jose, CA (US)

(21) Appl. No.: 18/631,149

(22) Filed: Apr. 10, 2024

(51) Int. Cl. H01L 23/00; H01L 25/18

(52) U.S. Cl. CPC H01L 24/08; H01L 24/06; H01L 24/80; H01L 25/18; H01L 2224/06133; H01L 2224/08145; H01L 2224/80125; H01L 2224/80895; H01L 2924/1438

(57) ABSTRACT

An apparatus includes a memory die having a 3D memory structure that includes nonvolatile memory cells in an array area. The nonvolatile memory cells are connected by word lines and bit lines. The word lines are connected to vertical word line vias in a staircase area adjacent to the array area. The vertical word line vias include a first plurality of vertical word line vias connected to first word line bond pads in the staircase area and a second plurality of vertical word line vias connected to second word line bond pads in the array area.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery).

One type of non-volatile memory has strings of non-volatile memory cells that have a select transistor at each end of the string. Typically, such strings are referred to as NAND strings and non-volatile memory chips or dies in which such NAND strings are formed may be referred to as NAND chips or dies.

In some examples, a silicon wafer that includes multiple non-volatile memory dies (e.g., NAND dies) may be bonded to another silicon wafer that includes an equal number of dies that include logic circuits (e.g., control dies, logic dies or Application Specific Integrated Circuits (ASICs)). Bonded wafers are then scribed (divided) into individual assemblies (integrated memory assemblies) that each include a memory die and a control die. Bond pads are provided on opposing surfaces to enable connection of logic circuits with components of a memory die (e.g., word lines and bit lines).

### BRIEF DESCRIPTION OF THE DRAWINGS

Like-numbered elements refer to common components in the different figures.

FIG. 1 (FIG. 1) is a functional block diagram of a memory device.

FIGS. 2A-B are block diagrams depicting embodiments of a memory system.

FIG. 3 is a perspective view of a portion of one embodiment of a monolithic three dimensional memory structure.

FIGS. 4A-C show an example of a nonvolatile memory structure.

FIG. 5 shows an example of wafer-to-wafer bonding.

FIGS. 6A-B illustrate an example of die-to-wafer bonding to form an integrated memory assembly.

FIGS. 7A-B illustrate another example of die-to-wafer bonding to form an integrated memory assembly.

FIGS. 8A-B illustrate another example of die-to-wafer bonding to form an integrated memory assembly.

FIGS. 9A-B illustrate another example of die-to-wafer bonding to form an integrated memory assembly.

FIGS. 10A-B illustrate another example of die-to-wafer bonding to form an integrated memory assembly.

FIGS. 11A-B illustrate examples of bond pads of a slot on a control die and corresponding bond pads on a memory chiplet respectively.

FIG. 12 illustrates an example of an integrated memory assembly.

FIG. 13 illustrates an example of array and staircase areas of a memory die.

FIG. 14 illustrates an example of array and staircase areas of a memory die bonded to a control die in an integrated memory assembly.

FIGS. 15A-B illustrate an example of routing of electrical connections in an integrated memory assembly.

FIGS. 16A-B illustrate an example of routing of electrical connections in an integrated memory assembly including word line bond pads in the array area.

FIGS. 17A-C illustrate examples of routing of traces to connect word line bond pads in an array area.

FIGS. 18A-B illustrate examples of patterns of bond pads.

FIG. 19 illustrates an example of a method that includes forming word line bond pads in an array area.

FIG. 20 illustrates an example of a method that includes forming traces that connect word line bond pads and that extend over bit lines.

### DETAILED DESCRIPTION

Techniques are provided for making integrated memory assemblies, which includes bonding memory dies or chiplets individually to a memory control circuit wafer in what may be referred to as die-to-wafer bonding. In contrast with wafer-to-wafer bonding, in which opposing dies of entire wafers are aligned and bonded, die-to-wafer bonding allows the number of memory dies and the characteristics of the individual memory dies to be selected (e.g., only non-defective memory dies having appropriate capacities). A control die may have multiple slots, each configured to interface with a memory chiplet. Some or all slots may be occupied by memory chiplets that may be identical or may have different characteristics to give a high degree of configurability.

When the size of a memory die is different to the size of a corresponding control die to which it is bonded (e.g., memory chiplet that is smaller than control die) bond pad placement may be limited and control circuits may not align with corresponding memory structure components (e.g., word line driver circuits in a control die may not align with word line vias in a corresponding memory die). Some control circuits may be located in overhang regions of a control die (regions that extend beyond connected memory dies). In some cases, die-to-wafer alignment may be less accurate than wafer-to-wafer alignment (more alignment noise) so that it may be desirable to configure bond pads in a manner that is tolerant of misalignment (e.g., enables larger bond pads and/or bond pad spacing).

Aspects of the present technology are directed to the technical problems of efficiently connecting control circuits in a control die with corresponding memory die components (e.g., where there is a size mismatch between dies and/or misalignment of control circuits and corresponding features which makes direct connection challenging and/or requirement for bond pad arrangement that has low sensitivity to misalignment). Solutions to these problems may include distributing word line bond pads over a wide area. For example, some word line bond pads may be located in an array area, over bit lines and memory cells, and may be connected to corresponding word line vias by traces that extend into the memory array area (bit line bond pads may also be located in the array area). Other word line bond pads may be located over corresponding word line vias with these differently connected vias interleaved (e.g., alternating between vias that are directly connected to overlying word line bond pads and vias that are connected by traces to bond pads in the array area). Traces may extend on either side of a row of vias. Bond pads may be arranged in a repeated hexagonal (honeycomb) arrangement for space-efficiency.

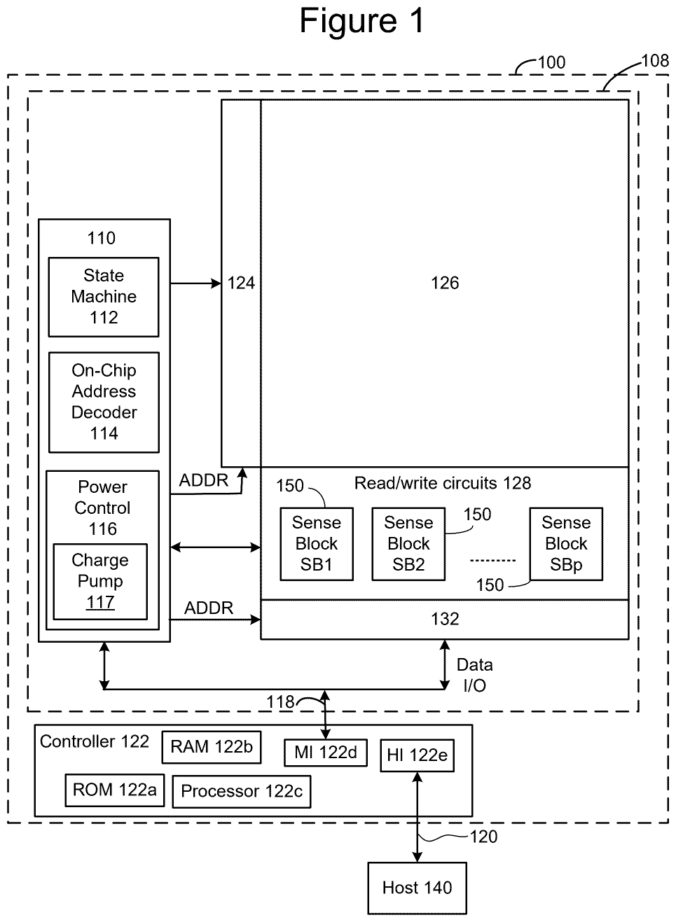

FIG. 1 is a functional block diagram of an example memory system 100. The components depicted in FIG. 1 are electrical circuits. Memory system 100 includes one or more memory dies 108. The one or more memory dies 108 can be complete memory dies or partial memory dies. In one embodiment, each memory die 108 includes a memory structure 126, control circuit 110, and read/write circuits 128. Memory structure 126 is addressable by word lines via a row decoder 124 and by bit lines via a column decoder 132. The read/write/erase circuits 128 include multiple sense blocks 150 including SB1, SB2, . . . , SBp (sensing circuits) and allow a page of memory cells to be read or programmed in parallel. Also, many strings of memory cells can be erased in parallel.

In some systems, a controller 122 is included in the same package (e.g., a removable storage card) as the one or more memory die 108. However, in other systems, the controller can be separated from the memory die 108. In some embodiments the controller will be on a different die than the memory die 108. In some embodiments, one controller 122 will communicate with multiple memory die 108. In other embodiments, each memory die 108 has its own controller. Commands and data are transferred between a host 140 and controller 122 via a data bus 120, and between controller 122 and the one or more memory die 108 via lines 118. In one embodiment, memory die 108 includes a set of input and/or output (I/O) pins that connect to lines 118.

Control circuit 110 cooperates with the read/write circuits 128 to perform memory operations (e.g., write, read, erase and others) on memory structure 126, and includes state machine 112, an on-chip address decoder 114, and a power control circuit 116. In one embodiment, control circuit 110 includes buffers such as registers, ROM fuses and other storage devices for storing default values such as base voltages and other parameters.

The on-chip address decoder 114 provides an address interface between addresses used by host 140 or controller 122 to the hardware address used by the decoders 124 and 132. Power control circuit 116 controls the power and voltages supplied to the word lines, bit lines, and select lines during memory operations. The power control circuit 116 includes voltage circuitry, in one embodiment. Power control circuit 116 includes charge pumps 117 for creating voltages. The sense blocks include bit line drivers. The power control circuit 116 executes under control of the state machine 112, in one embodiment.

State machine 112 and/or controller 122 (or equivalently functioned circuits), in combination with all or a subset of the other circuits depicted in FIG. 1, can be considered a control circuit that performs various functions described herein. The control circuit can include hardware only or a combination of hardware and software (including firmware). For example, a controller programmed by firmware to perform the functions described herein is one example of a control circuit. A control circuit can include a processor, PGA (Programmable Gate Array, FPGA (Field Programmable Gate Array), ASIC (Application Specific Integrated Circuit), integrated circuit or other type of circuit.

The (on-chip or off-chip) controller 122 (which in one embodiment is an electrical circuit) may comprise one or more processors 122c, ROM 122a, RAM 122b, a memory interface (MI) 122d and a host interface (HI) 122e, all of which are interconnected. The storage devices (ROM 122a, RAM 122b) store code (software) such as a set of instructions (including firmware), and one or more processors 122c is/are operable to execute the set of instructions to provide the functionality described herein. Alternatively, or additionally, one or more processors 122c can access code from a storage device in the memory structure, such as a reserved area of memory cells connected to one or more word lines. RAM 122b can store data for controller 122, including caching program data (discussed below). Memory interface 122d, in communication with ROM 122a, RAM 122b and processor 122c, is an electrical circuit that provides an electrical interface between controller 122 and one or more memory die 108. For example, memory interface 122d can change the format or timing of signals, provide a buffer, isolate from surges, latch I/O, etc. One or more processors 122c can issue commands to control circuit 110 (or another component of memory die 108) via Memory Interface 122d. Host interface 122e provides an electrical interface with host 140 data bus 120 in order to receive commands, addresses and/or data from host 140 to provide data and/or status to host 140.

In one embodiment, memory structure 126 comprises a three-dimensional memory array of non-volatile memory cells in which multiple memory levels are formed above a single substrate, such as a wafer. The memory structure may comprise any type of non-volatile memory that are monolithically formed in one or more physical levels of arrays of memory cells having an active area disposed above a silicon (or other type of) substrate. In one example, the non-volatile memory cells comprise vertical NAND strings with charge-trapping material.

In another embodiment, memory structure 126 comprises a two-dimensional memory array of non-volatile memory cells. In one example, the non-volatile memory cells are NAND flash memory cells utilizing floating gates. Other types of memory cells (e.g., NOR-type flash memory) can also be used. The exact type of memory array architecture or memory cell included in memory structure 126 is not limited to the examples above.

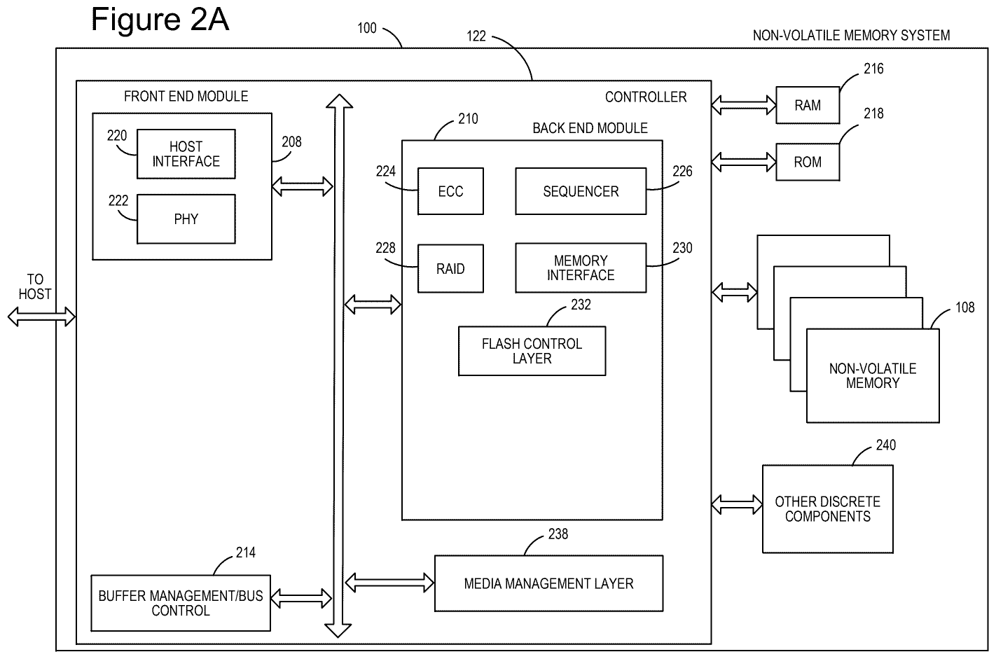

FIG. 2A is a block diagram of example memory system 100, depicting more details of one embodiment of controller 122. The controller in FIG. 2A is a flash memory controller but note that the non-volatile memory die 108 is not limited to flash. Thus, the controller 122 is not limited to the example of a flash memory controller. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between controller 122 and non-volatile memory die 108 may be any suitable flash interface, such as Toggle Mode 200, 400, or 800. In one embodiment, memory system 100 may be a card-based system, such as a secure digital (SD) or a micro secure digital (micro-SD) card. In an alternate embodiment, memory system 100 may be part of an embedded memory system. For example, the flash memory may be embedded within the host. In other examples, memory system 100 can be in the form of a solid state drive (SSD).

In some embodiments, memory system 100 includes a single channel between controller 122 and non-volatile memory die 108, the subject matter described herein is not limited to having a single memory channel. For example, in some memory system architectures, 2, 4, 8 or more channels may exist between the controller and the memory die, depending on controller capabilities. In any of the embodiments described herein, more than a single channel may exist between the controller and the memory die, even if a single channel is shown in the drawings.

As depicted in FIG. 2A, controller 122 includes a front end module 208 that interfaces with a host, a back end module 210 that interfaces with the one or more non-volatile memory die 108, and various other modules that perform functions which will now be described in detail.

The components of controller 122 depicted in FIG. 2A may take the form of a packaged functional hardware unit (e.g., an electrical circuit) designed for use with other components, a portion of a program code (e.g., software or firmware) executable by a (micro) processor or processing circuits that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively, or in addition, each module may include software stored in a processor readable device (e.g., memory) to program a processor for controller 122 to perform the functions described herein. The architecture depicted in FIG. 2A is one example implementation that may (or may not) use the components of controller 122 depicted in FIG. 1 (i.e., RAM, ROM, processor, interface).

Referring again to modules of the controller 122, a buffer manager/bus control 214 manages buffers in random access memory (RAM) 216 and controls the internal bus arbitration of controller 122. A read only memory (ROM) 218 stores system boot code. Although illustrated in FIG. 2A as located separately from the controller 122, in other embodiments one or both of the RAM 216 and ROM 218 may be located within the controller. In yet other embodiments, portions of RAM and ROM may be located both within the controller 122 and outside the controller. Further, in some implementations, the controller 122, RAM 216, and ROM 218 may be located on separate semiconductor die.

Front end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back end module 210 includes an error correction code (ECC) engine 224 that encodes the data bytes received from the host and decodes and error corrects the data bytes read from the non-volatile memory. A command sequencer 226 generates command sequences, such as program and erase command sequences, to be transmitted to non-volatile memory die 108. A RAID (Redundant Array of Independent Dies) module 228 manages generation of RAID parity and recovery of failed data. The RAID parity may be used as an additional level of integrity protection for the data being written into the memory system 100. In some cases, the RAID module 228 may be a part of the ECC engine 224. Note that the RAID parity may be added as an extra die or dies as implied by the common name, but it may also be added within the existing die, e.g., as an extra plane, or extra block, or extra WLs within a block. A memory interface 230 provides the command sequences to non-volatile memory die 108 and receives status information from non-volatile memory die 108. In one embodiment, memory interface 230 may be a double data rate (DDR) interface, such as a Toggle Mode 200, 400, or 800 interface. A flash control layer 232 controls the overall operation of back end module 210.

Additional components of memory system 100 illustrated in FIG. 2A include media management layer 238, which performs wear leveling of memory cells of non-volatile memory die 108. Memory system 100 also includes other discrete components 240, such as external electrical interfaces, external RAM, resistors, capacitors, or other components that may interface with controller 122. In alternative embodiments, one or more of the physical layer interface 222, RAID module 228, media management layer 238 and buffer management/bus controller 214 are optional components that are not necessary in the controller 122.

The Flash Translation Layer (FTL) or Media Management Layer (MML) 238 may be integrated as part of the flash management that may handle flash errors and interfacing with the host. In particular, MML may be a module in flash management and may be responsible for the internals of NAND management. In particular, the MML 238 may include an algorithm in the memory device firmware which translates writes from the host into writes to the memory structure 126 of memory die 108. The MML 238 may be needed because: 1) the memory may have limited endurance; 2) the memory structure 126 may only be written in multiples of pages; and/or 3) the memory structure 126 may not be written unless it is erased as a block (or a tier within a block in some embodiments). The MML 238 understands these potential limitations of the memory structure 126 which may not be visible to the host. Accordingly, the MML 238 attempts to translate the writes from host into writes into the memory structure 126.

Controller 122 may interface with one or more memory dies 108. In one embodiment, controller 122 and multiple memory dies (together comprising memory system 100) implement a solid state drive (SSD), which can emulate, replace or be used instead of a hard disk drive inside a host, as a NAS device, in a laptop, in a tablet, in a server, etc. Additionally, the SSD need not be made to work as a hard drive.

Some embodiments of a non-volatile storage system will include one memory die 108 connected to one controller 122. However, other embodiments may include multiple memory die 108 in communication with one or more controllers 122. In one example, the multiple memory die can be grouped into a set of memory packages. Each memory package includes one or more memory die in communication with controller 122. In one embodiment, a memory package includes a printed circuit board (or similar structure) with one or more memory die mounted thereon. In some embodiments, a memory package can include molding material to encase the memory dies of the memory package. In some embodiments, controller 122 is physically separate from any of the memory packages.

In one embodiment, the control circuit(s) (e.g., control circuits 110) are formed on a first die, referred to as a control die, and the memory array (e.g., memory structure 126) is formed on a second die, referred to as a memory die. For example, some or all control circuits (e.g., control circuit 110, row decoder 124, column decoder 132, and read/write circuits 128) associated with a memory may be formed on the same control die. A control die may be bonded to one or more corresponding memory die to form an integrated memory assembly. The control die and the memory die may have bond pads arranged for electrical connection to each other. Bond pads of the control die and the memory die may be aligned and bonded together by any of a variety of bonding techniques, depending in part on bond pad size and bond pad spacing (i.e., bond pad pitch). In some embodiments, the bond pads are bonded directly to each other, without solder or other added material, in a so-called Cu-to-Cu bonding process. In some examples, dies are bonded in a one-to-one arrangement (e.g., one control die to one memory die). In some examples, there may be more than one control die and/or more than one memory die in an integrated memory assembly. In some embodiments, an integrated memory assembly includes a stack of multiple control die and/or multiple memory die. In some embodiments, the control die is connected to, or otherwise in communication with, a memory controller. For example, a memory controller may receive data to be programmed into a memory array. The memory controller will forward that data to the control die so that the control die can program that data into the memory array on the memory die.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 307. One or more integrated memory assemblies 307 may be used in a memory package in memory system 100. The integrated memory assembly 307 includes two types of semiconductor die (or more succinctly, “die”). Memory die 301 includes memory structure 126.

Control die 311 includes column control circuits 364, row control circuits 320 and system control logic 360 (including state machine 312, power control module 316 (including charge pumps 117), storage 366, and memory interface 368). In some embodiments, control die 311 is configured to connect to the memory structure 126 in the memory die 301. FIG. 2B shows an example of the peripheral circuits, including control circuits, formed in a peripheral circuit or control die 311 coupled to memory array 126 formed in memory die 301. System control logic 360, row control circuits 320, and column control circuits 364 are located in control die 311. In some embodiments, all or a portion of the column control circuits 364 and all or a portion of the row control circuits 320 are located on the memory die 301. In some embodiments, some of the circuits in the system control logic 360 are located on the on the memory die 301.

System control logic 360, row control circuits 320, and column control circuits 364 may be formed by a common process (e.g., CMOS process), so that adding elements and functionalities, such as ECC, more typically found on a memory controller 102 may require few or no additional process steps (i.e., the same process steps used to fabricate memory controller 102 may also be used to fabricate system control logic 360, row control circuits 320, and column control circuits 364). Thus, while moving such circuits from a die such as memory die 301 may reduce the number of steps needed to fabricate such a die, adding such circuits to a die such as control die 311 may not require many additional process steps.

FIG. 2B shows column control circuits 364 including sense block(s) 350 on the control die 311 coupled to memory array 126 on the memory die 301 through electrical paths 370. For example, electrical paths 370 may provide electrical connection between column decoder 332, driver circuits 372 (bit line driver circuits), and block select 373 and bit lines of memory array (or memory structure) 126. Electrical paths may extend from column control circuits 364 in control die 311 through pads on control die 311 that are bonded to corresponding pads of the memory die 301, which are connected to bit lines of memory structure 126. Each bit line of memory structure 126 may have a corresponding electrical path in electrical paths 370, including a pair of bond pads, which connects to column control circuits 364. Similarly, row control circuits 320, including row decoder 324, array drivers 374 (word line driver circuits), and block select 376 are coupled to memory array 126 through electrical paths 308. Each of electrical paths 308 may correspond to a word line, dummy word line, or select gate line. Additional electrical paths may also be provided between control die 311 and memory die 301.

In some embodiments, there is more than one control die 311 and/or more than one memory die 301 in an integrated memory assembly 307. In some embodiments, the integrated memory assembly 307 includes a stack of multiple control die 311 and multiple memory dies 301. In some embodiments, each control die 311 is affixed (e.g., bonded) to at least one of the memory dies 301.

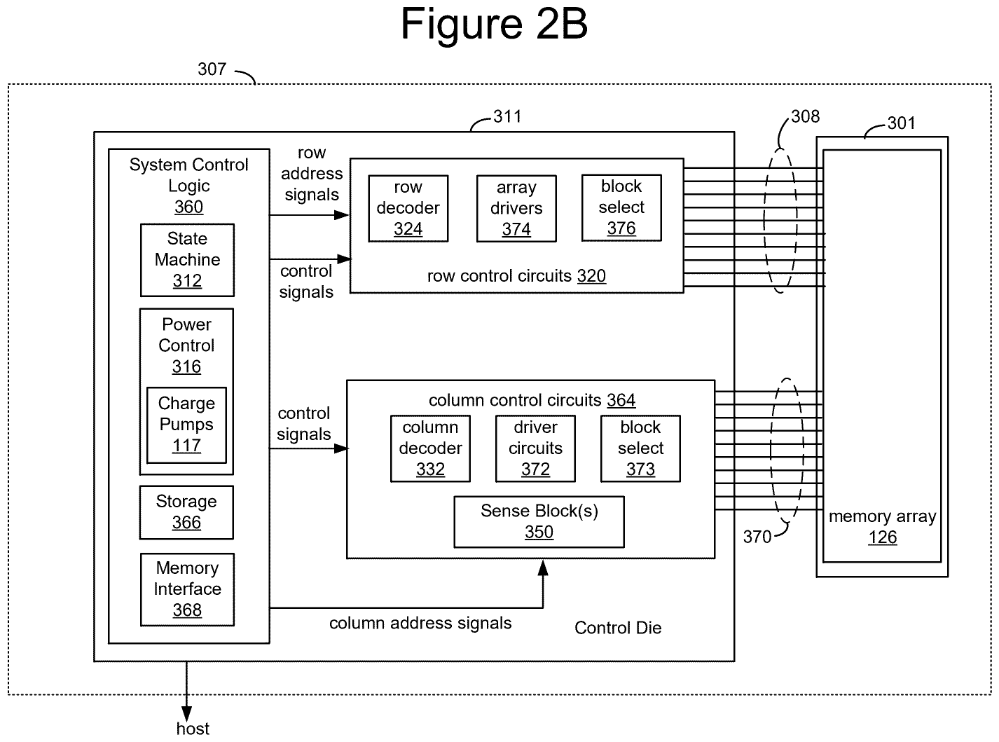

FIG. 3 is a perspective view of a portion of one example embodiment of a monolithic three dimensional memory array that can comprise memory structure 126, which includes a plurality of non-volatile memory cells. For example, FIG. 3 shows a portion of one block of memory. The structure depicted includes a set of bit lines BL positioned above a stack of alternating layers of dielectric material and conductive material on a substrate. For example, one of the dielectric layers is marked as D and one of the conductive layers (also called word line layers) is marked as W. The number of alternating dielectric layers and conductive layers can vary based on specific implementation requirements. One set of embodiments includes between 108-300 alternating dielectric layers and conductive layers. One example embodiment includes 96 data word line layers, 8 select layers, 6 dummy word line layers and 110 dielectric layers. More or less than 108-300 layers can also be used. Data word line layers have data memory cells. Dummy word line layers have dummy memory cells. As will be explained below, the alternating dielectric layers and conductive layers are divided into “fingers” in regions that are separated by local interconnects LI. FIG. 3 shows two regions, each with respective NAND strings, and two local interconnects LI. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data.

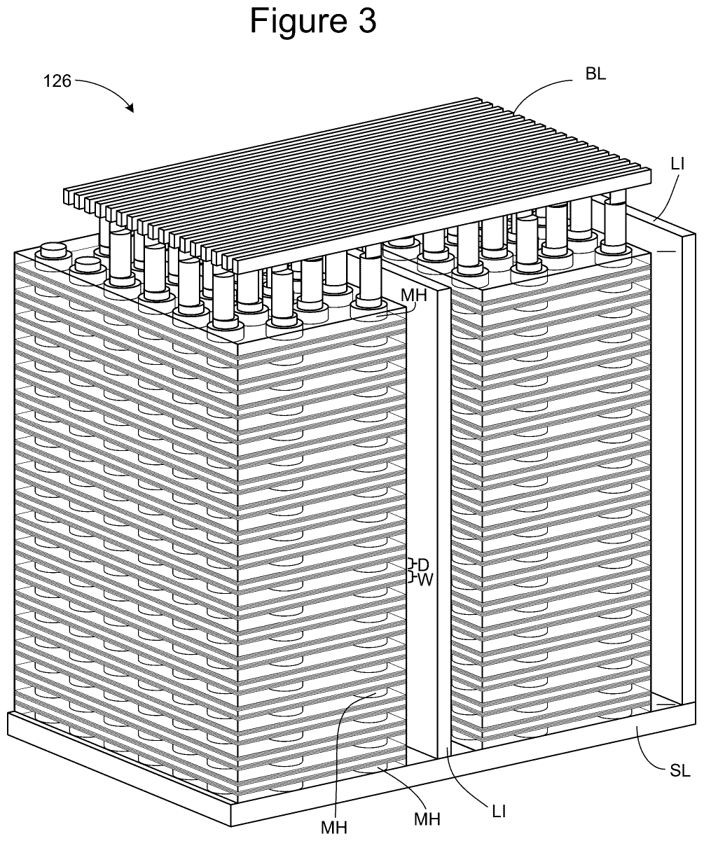

FIG. 4A is a block diagram explaining one example organization of memory structure 126, which is divided into two planes 302 and 304. Each plane is then divided into M blocks. In one example, each plane has about 2000 blocks. However, different numbers of blocks and planes can also be used. In one embodiment, for two plane memory, the block IDs are usually such that even blocks belong to one plane and odd blocks belong to another plane; therefore, plane 302 includes block 0, 2, 4, 6, . . . and plane 304 includes blocks 1, 3, 5, 7, . . . . In one embodiment, a block of memory cells is a unit of erase. That is, all memory cells of a block are erased together. In other embodiments, memory cells can be grouped into blocks for other reasons, such as to organize the memory structure 126 to enable the signaling and selection circuits.

FIGS. 4B-4C depict an example 3D NAND structure. FIG. 4B is a block diagram depicting a top view of a portion of one block from memory structure 126. The portion of the block depicted in FIG. 4B corresponds to portion 306 in block 2 of FIG. 4A. In one embodiment, the memory array will have 60 layers. Other embodiments have less than or more than 60 layers (e.g.,. However, FIG. 4B only shows the top layer.

FIG. 4B depicts a plurality of circles that represent the vertical columns. Each of the vertical columns include multiple select transistors and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. The block may include more vertical columns than depicted in FIG. 4B.

FIG. 4B also depicts a set of bit lines 425, including bit lines 411, 412, 413, 414, . . . 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side select lines and the drain side select lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of an embodiment of three-dimensional memory structure 126 showing a cross-sectional view along line AA of FIG. 4B. This cross-sectional view cuts through vertical columns 432 and 434 and region 430 (see FIG. 4B). The structure of FIG. 4C includes four drain side select layers SGD0, SGD1, SGD2 and SGD3; four source side select layers SGS0, SGS1, SGS2 and SGS3; four dummy word line layers DD0, DD1, DS0 and DS1; and forty-eight data word line layers WLL0-WLL47 for connecting to data memory cells. Other embodiments can implement more or less than four drain side select layers, more or less than four source side select layers, more or less than four dummy word line layers, and more or less than forty-eight-word line layers (e.g., 96 word line layers or more than 100 word line layers). Vertical columns 432 and 434 are depicted protruding through the drain side select layers, source side select layers, dummy word line layers and word line layers. In one embodiment, each vertical column comprises a NAND string. For example, vertical column 432 comprises NAND string 484. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to bit line 414 via connector 415. Local interconnects 404 and 406 are also depicted.

Bit line 414 is connected to pad 416 by bit line via 417. Additional bit lines that are coupled to additional vertical columns are similarly connected. A number of bit lines may extend over such a memory structure and may connect to multiple blocks through block select circuits. Such bit lines are connected to pads that may be exposed along a top surface (primary surface) of a work piece so that they can be used to form electrical connection. Similarly, word lines (e.g. WLL0-WLL47), dummy word lines (e.g. DD0-1, DS0-1), and select lines (e.g. SGD0-SGD3) may be coupled by word line vias (not shown in FIG. 4C) to pads on the primary surface of a workpiece (e.g. pads that are co-planar with pad 416). For example, word line layers may be arranged in a stepped “staircase” arrangement in an outer area (outside area where memory cells are formed) so that each word line layer is exposed and can be contacted by a via.

The non-volatile memory cells are formed along vertical columns which extend through alternating conductive and dielectric layers in the stack. In one embodiment, the memory cells are arranged in NAND strings. The word line layer WLL0-WLL47 connect to memory cells (also called data memory cells). Dummy word line layers DD0, DD1, DS0 and DS1 connect to dummy memory cells. A dummy memory cell does not store user data, while a data memory cell is eligible to store user data. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

The exact type of memory array architecture or memory cell included in memory structure 126 is not limited to the examples above. Many different types of memory array architectures or memory cell technologies can be used to form memory structure 126. No particular non-volatile memory technology is required for purposes of the new claimed embodiments proposed herein. Other examples of suitable technologies for memory cells of the memory structure 126 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 126 include two dimensional arrays, three dimensional arrays, cross-point arrays, stacked two dimensional arrays, vertical bit line arrays, and the like. A person of ordinary skill in the art will recognize that the technology described herein is not limited to a single specific memory structure, but covers many relevant memory structures within the spirit and scope of the technology as described herein and as understood by one of ordinary skill in the art.

One example of a ReRAM memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a spin valve and is the simplest structure for an MRAM bit. A memory device is built from a grid of such memory cells. In one embodiment for programming a non-volatile storage system, each memory cell lies between a pair of write lines arranged at right angles to each other, parallel to the cell, one above and one below the cell. When current is passed through them, an induced magnetic field is created.

Phase change memory (PCRAM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse but includes a (continuous or non-continuous) vibration or burst of sound, current, voltage light, or other wave.

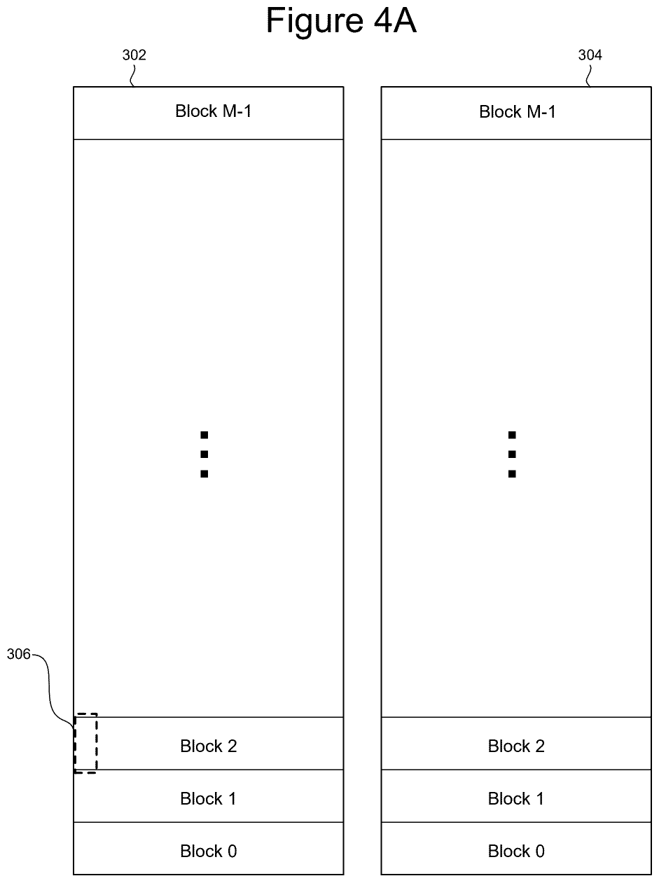

FIG. 5 illustrates the process of wafer-to-wafer bonding of wafer 500 and wafer 600. Substrate 501 is processed to fabricate memory dies that include nonvolatile memory arrays (e.g. memory structure 126), interconnect structures, and pads for bonding as discussed above with respect to FIGS. 3 and 4A-C, thereby forming wafer 500. Substrate 601 is processed to fabricate control dies that include memory control circuits (e.g. logic circuits formed as CMOS circuits), interconnect structures, and pads for bonding as discussed above with respect to FIG. 2B, thereby forming wafer 600. Wafer 500 is then flipped over in this example (either wafer may be flipped) so that primary surface 506 of wafer 500 opposes primary surface 606 of wafer 600. Wafers 500 and 600 are aligned so that corresponding dies are aligned in pairs (in a one-to-one arrangement of memory dies and control dies) and pads on such pairs of dies are aligned for bonding. Subsequently, with wafers 500, 600 aligned, pressure and/or heat or other conditions are applied to wafers 500, 600 to bond respective pads together and thus form electrical connections between memory arrays of wafer 500 and control circuits of wafer 600 (i.e. bonded along an interface between primary surfaces 506, 606). Bonded wafers 500 and 600 form a combined wafer 700 that includes pairs of dies, with each pair including a memory die and a control die that form a memory system. Combined wafer 700 may be scribed (diced) into pairs of dies 702 for packaging. Combined wafer 700 or a portion of such a wafer may be referred to as a CMOS bonded Array (CbA) and an individual pair of dies 702 (memory die and control die) may be referred to as an integrated memory assembly.

One feature of wafer-to-wafer bonding as described with respect to FIG. 5 is die-size matching (e.g., the one-to-one relationship between memory dies and control dies may require both dies to have identical dimensions). In some cases, such a one-to-one correspondence may not be optimal. For example, as the number of word line layers in 3D memory structures and the number of bits per memory cell increase, memory density increases, which may allow a reduction in memory die size. Reduction in control die size (e.g., due to reduced minimum feature size) may not match reduction in memory die size. In order to maintain equal sizing of memory and control die for die-size matching, memory die size may be larger than necessary, which may be costly (e.g., memory wafers may be more expensive to manufacture than control circuit wafers so that wasted space on a memory die may be expensive) and may obviate the advantages that may be obtained from high density memory structures.

Another feature of the one-to-one relationship between memory dies and control dies of FIG. 5 is that the failure rate for integrated memory assemblies may be relatively high and a number of “good” dies (memory dies and control dies that meet a specification and are not defective) may be wasted. Good memory dies may be bonded to bad control dies and good control dies may be bonded to bad memory dies resulting in bad integrated memory assemblies. For example, where 5% of memory dies are bad (defective) and 5% of control dies are bad (defective) the resulting yield loss may be about 10% (e.g., about 10% of resulting integrated memory assemblies are defective because of either a defective memory die or a defective control die). Even if bad dies are identified prior to bonding, wafer-to-wafer bonding may not allow any rearrangement of die pairing (e.g., a given die is paired with a corresponding die based on its physical location in a wafer, which may not be changeable prior to wafer-to-wafer bonding).

According to aspects of the present technology, integrated memory assemblies may be formed in a manner that is not limited to the one-to-one arrangement of FIG. 5, is not constrained by die-size matching and may allow integration of high-density memory structures in an efficient manner with lower failure rates than wafer-to-wafer bonding (e.g., fewer defective integrated memory assemblies for given die failure rates). According to examples presented below, two or more memory dielets or chiplets (e.g., memory dies such as memory die 301 having a memory structure 126 that may form one or more plane or sub-plane and that is not limited by die-size matching) may be combined with (e.g., directly bonded to) a control die that has slots (e.g., bond pad arrangements connected to corresponding control circuits) to accommodate multiple memory chiplets. Each memory chiplet may consist of an appropriate unit of a memory structure (e.g., one, two or more planes or sub-planes of NAND memory). Memory chiplets in such an arrangement may be identical or different. For example, chiplets may have different capacities (e.g., number of planes or blocks), different structures (e.g., different numbers of layers), different configurations (e.g., configured to store different numbers of bits per cell) and/or otherwise be non-identical. Such an arrangement may be adaptable to different needs (e.g., capacity is configurable by using chiplets of different capacities and/or different numbers of chiplets) and may combine high-performance and low-cost (e.g., some high-performance chiplets for demanding applications and some low-cost chiplets for less demanding applications). Testing of chiplets and/or control dies prior to assembly may reduce the number of defective integrated memory assemblies (e.g., compared with wafer-to-wafer bonding). For example, defective control dies in a wafer may be identified, marked as defective and may not be bonded to any chiplets while defective chiplets may be identified and discarded without being bonded to any control dies. Such die screening prior to bonding may have significant benefits. For example, where 5% of memory chiplets and 5% of control dies are defective, the defective memory chiplets are discarded and the remaining good memory chiplets (95%) are bonded to good control dies (no bonding to the 5% of control dies that are defective) so that the yield loss is limited to 5% (e.g., about half of the yield loss wafer-to-wafer bonding of similar dies).

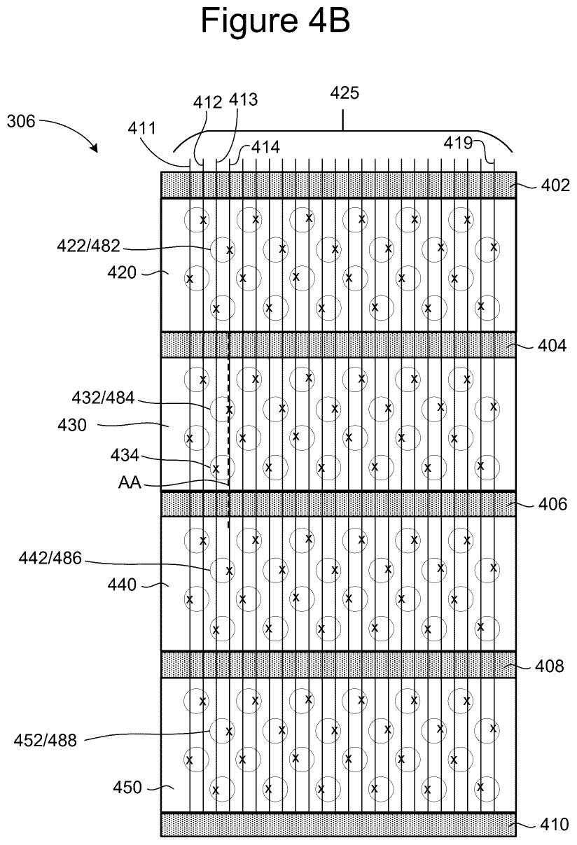

FIGS. 6A-B show an example of die-to-wafer bonding in which four memory chiplets (memory dies) 610a-d are bonded to a control die 612 in a silicon wafer 600. For example, silicon wafer 600 may include a large number of control dies including control dies 612 and 614 shown in FIG. 6A. In some cases, one or more defective control dies may be detected prior to assembly of integrated memory assemblies (e.g., prior to bonding memory chiplets to control dies as shown in FIG. 6A). In the example shown, control die 614 is detected as a defective control die and consequently no memory chiplets are bonded to control die 614. Unlike the wafer-to-wafer bonding example of FIG. 5, bonding may be selective on a die-by-die basis so that defective dies may be omitted from bonding thereby saving resources.

FIG. 6B shows a top-down view of control die 612 showing upper (first) surface 616, which includes four slots 616a-d corresponding to the four memory chiplets 610a-d. Each slot 616a-d may include bond pads for bonding to corresponding bond pads of memory chiplets 610a-d and each slot may have dimensions to accommodate a memory chiplet (e.g., dimensions equal to or greater than those of an opposing (second) surface of a memory chiplet or die). Each memory chiplet may be individually aligned and bonded. For example, memory chiplet 610a may be aligned with corresponding control die 612 and bonded to corresponding slot 616a, subsequently, memory chiplet 610b may be aligned with corresponding control die 612 and bonded to corresponding slot 616b and so on until the desired number of memory chiplets are bonded to control die 612. Subsequently, memory chiplets may be aligned and bonded to additional control dies of wafer 600 (omitting defective control dies such as control die 614). In some examples, the order of such bonding may be different to the example above.

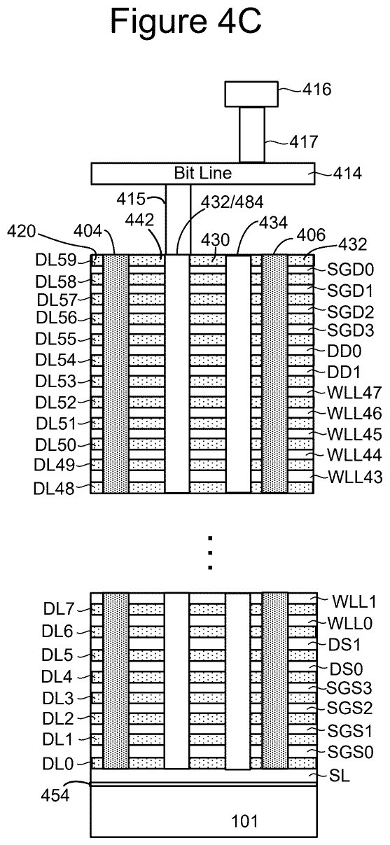

FIGS. 7A-B show another example of die-to-wafer bonding in which eight memory chiplets (memory dies) 620a-h are bonded to a control die 622 in a silicon wafer 600. For example, silicon wafer 600 may include a large number of control dies including control dies 622 and 624 shown in FIG. 7A. Defective control dies may be detected prior to assembly of integrated memory assemblies (e.g., prior to bonding memory chiplets to control dies as shown in FIG. 7A). In the example shown, control die 624 is detected as a defective control die and consequently no memory chiplets are bonded to control die 624.

FIG. 7B shows a top-down view of control die 622 showing upper (first) surface 626, which includes eight slots 626a-h corresponding to the eight memory dies 620a-h. Each slot 626a-h may include bond pads for bonding to corresponding bond pads of memory dies 620a-h and each slot may have dimensions to accommodate a memory die (e.g., dimensions equal to or greater than those of an opposing (second) surface of a memory chiplet or die).

While the examples of FIGS. 6A-7B show four and eight slots respectively, the number of slots and the arrangement of slots are not limited to any particular number or arrangement. The examples described here are for purposes of illustration and are not intended to provide an exhaustive list of all possible implementations. Furthermore, the control dies in a given silicon wafer may not be identical. For example, a single silicon wafer may include control dies having four slots (e.g., control die 612) and control dies having eight slots (e.g., control die 622) or dies that are otherwise different.

In addition to providing flexibility as to whether to bond dies (e.g., only bonding good dies), aspect of the present technology may provide flexibility as to how many memory chiplets and what type(s) of memory chiplets to bond to a given control die. It is not generally required that every slot on a control die be occupied by a memory chiplet in order to form a functional integrated memory assembly.

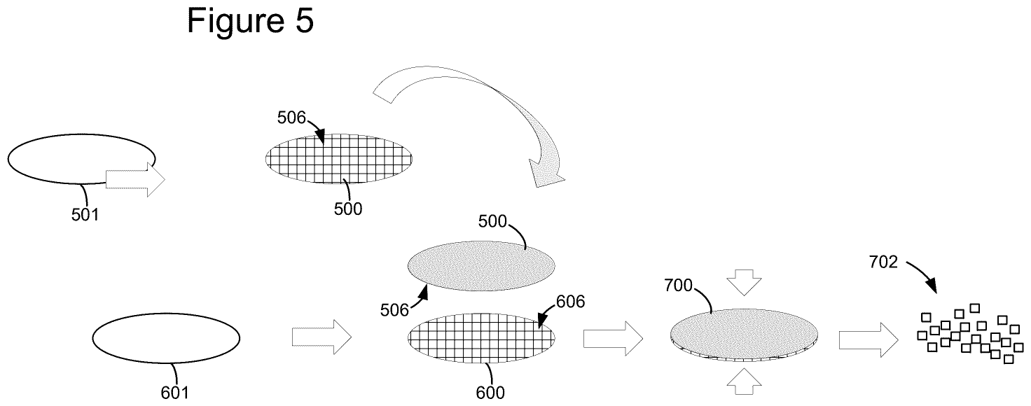

For example, FIGS. 8A-B show the case where control die 612 has four slots 616a-d with two used (occupied) slots, 616a and 616c, and two unused (empty) slots, 616b and 616d. Memory chiplets 610a and 610c are bonded in corresponding slots 616a and 616c, while no memory chiplets are bonded in slots 616b and 616d, which remain empty. The assembly consisting of control die 612 and memory chiplets 610a and 610c may be considered a completed integrated memory assembly.

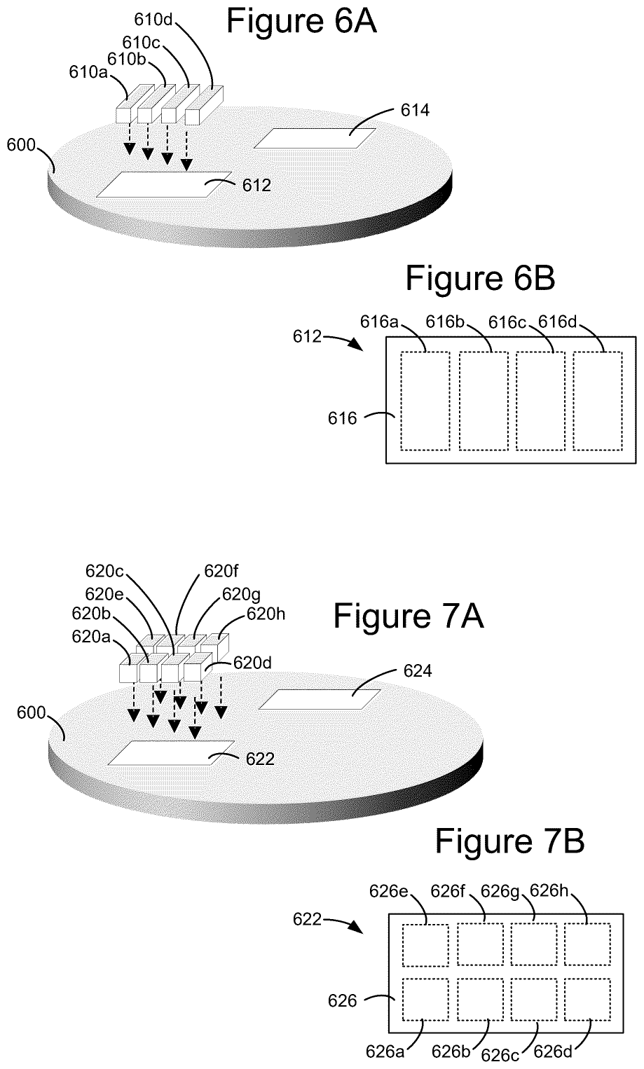

FIGS. 9A-B show another example in which control die 622 has eight slots 626a-h, with six slots, 626a and 626c-g, used and two slots, 626b and 626h, unused. Memory chiplets 620a and 620c-g are bonded in corresponding slots 626a and 626c-g, while no memory chiplets are bonded in slots 626b and 626h, which remain empty. The assembly consisting of control die 622 and memory chiplets 620a and 620c-g may be considered a completed integrated memory assembly.

According to aspects of the present technology, an integrated memory assembly may be formed using two or more different memory chiplets (e.g., memory chiplets having different structures, capacities, configurations and/or that are otherwise different). For example a memory die of a first type and an additional memory die of a second type.

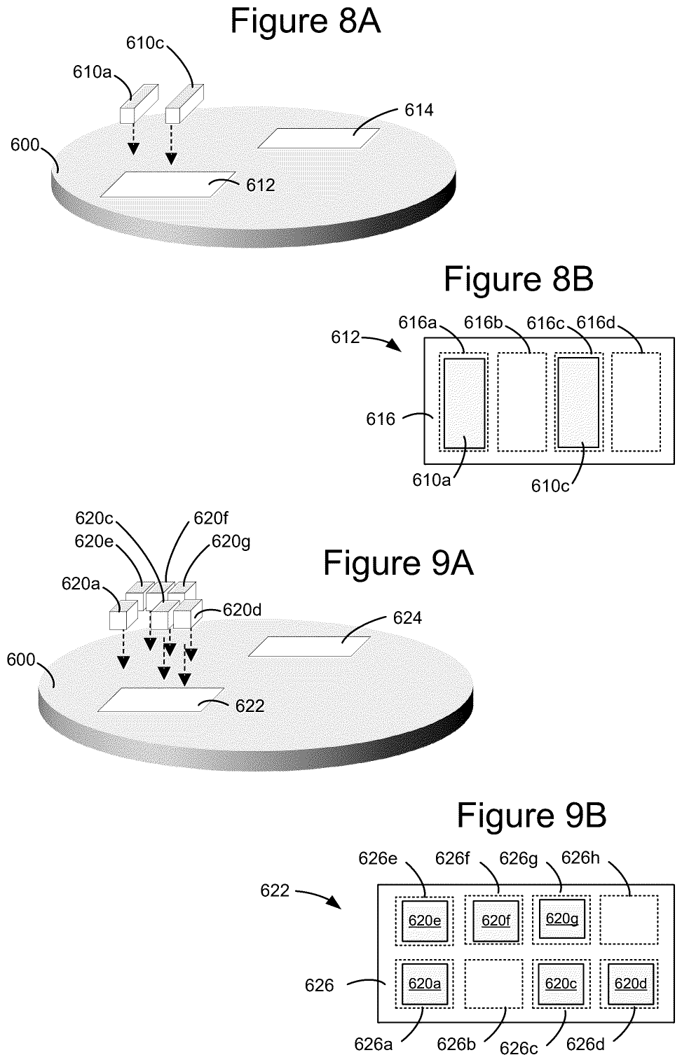

FIGS. 10A-B show an example in which non-identical memory chiplets are bonded to control die 622 to form an integrated memory assembly. Memory chiplets 630a and 630c-g are not identical. For example, memory chiplet 630a is physically larger than memory chiplets 630c-g and occupies two slots, 626a and 626e. Memory chiplet 630a may be designed to interface with bond pads of two slots so that it can be bonded as shown (e.g., a slot may define a minimum memory chiplet footprint and bond pad arrangement without limiting chiplet size to a single slot). Memory chiplet 630c is smaller than memory chiplet 630a (e.g., approximately half the size) and may have a smaller capacity accordingly (e.g., half the capacity where structure and configuration are similar). Memory chiplet 630d has a greater number of layers than memory chiplet 630c (e.g., more word line layers and more memory cells, which provide more data storage capacity). Memory chiplet 630f has a different configuration to memory chiplet 630c (for example, whereas memory chiplet 630c may be configured to store four bits per cell (QLC), memory chiplet 630f may be configured to store three bits per cell (TLC) or one bit per cell (SLC)). Memory chiplet 630g may have a different structure to memory chiplet 630c. For example, while memory chiplet 630c may have a 3D NAND flash memory structure, memory chiplet 630g may have a different structure (e.g., ReRAM, MRAM, PCM or other structure). While the different memory chiplets shown in FIGS. 10A-B are provided as examples, the range of memory chiplets that may be bonded to a single control die is not limited to the examples described.

Forming an integrated memory assembly from memory chiplets that have different characteristics allows customization of integrated memory assemblies for particular uses in a cost-effective manner (e.g., combining high-performance memory chiplets with cheaper, low-performance memory chiplets). Memory chiplets manufactured using older technology may be integrated with memory chiplets using newer technology to obtain the benefits of newer technology at a lower total cost. The data storage capacities of such integrated memory assemblies may be configured by selecting the number and capacities of memory chiplets used. A common control die design may be used to provide integrated memory assemblies with a range of different capacities. Integrated memory assemblies with different capacities (and/or other different characteristics) may be formed in the same manufacturing facility and may be formed from the same silicon wafer (e.g., silicon wafer 600 may include control dies that are bonded to a different set of memory chiplets than those bonded to control die 622).

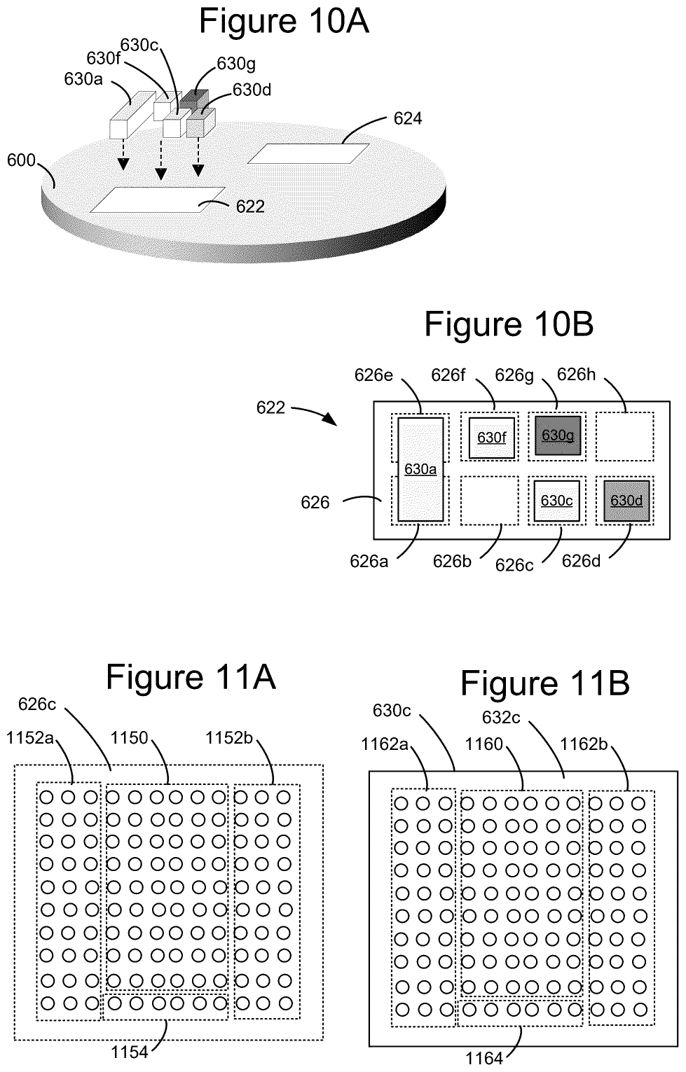

Bond pads of a slot (e.g., any off slots 626a-h on upper surface 626 of FIG. 10B) may be arranged to align with correspond bond pads on a (second) surface of a memory chiplet. FIG. 11A shows an example of bond pads of slot 626c, which includes bit line bond pads 1150 located in the middle of slot 626c and word line bond pads 1152a, 1152b located on either side of bit line bond pads 1150. Bit line bond pads 1150 may be connected to bit line driver circuits (e.g., driver circuits 372 of column control circuits 364) in control die 622. Worldline bond pads 1152a-b may be connected to word line driver circuits (e.g., array drivers 374 of row control circuits 320) in control die 622. Additional bond pads 1154 are provided in slot 626c and may include pads providing one or more voltages, for example ground or 0 volts; supply voltage(s) such as 3 volts, 5 volts or other nonzero voltage, one or more clock signal and/or voltages or signals that may be used by a memory chiplet.

FIG. 11B shows corresponding bond pads on a surface 632c (second surface) of memory chiplet 630c that correspond to (and, in FIG. 10B are bonded to) bond pads of slot 626c shown in FIG. 11A. FIG. 11B shows bit line bond pads 1160 located in the middle of surface 632c and word line bond pads 1162a, 1156b located on either side of bit line bond pads 1160. Bit line bond pads 1160 may be connected to bit lines in memory chiplet 630c (e.g., pad 416 connected to bit line 414 in FIG. 4C). Word line bond pads 1162a-b may be connected to word lines in memory chiplet 630c (e.g., word lines WLL0 to WLL47 of FIG. 4C). Additional bond pads 1164 are provided on surface 632c and may correspond to additional bond pads 1154 (e.g., pads for one or more voltage(s), clock signal(s) and/or other signals).

During manufacturing of an integrated memory assembly, a memory chiplet may be aligned so that bond pads of the memory chiplet align with corresponding bond pads of a slot on a surface of a control die. For example, memory chiplet 630c is aligned with slot 626c so that bit line bond pads 1150 (first bit line bond pads) of slot 626c and bit line bond pads 1160 (second bit line bond pads) on surface 632c are aligned, first word line bond pads 1152a-b and second word line bond pads 1162a-b are aligned and first additional bond pads 1154 and second additional bond pads 1164 are aligned. Bonding of bond pads may then be performed so that first bit line bond pads 1150 are bonded to second bit line bond pads 1160, first word line bond pads 1152a-b are bonded to second word line bond pads 1162a-b and first additional bond pads 1154 are bonded to second additional bond pads 1164, which results in connection of control circuits in control die 622 with corresponding components of memory chiplet 630c (e.g., bit line drivers connected to bit lines and word line drivers connected to word lines).

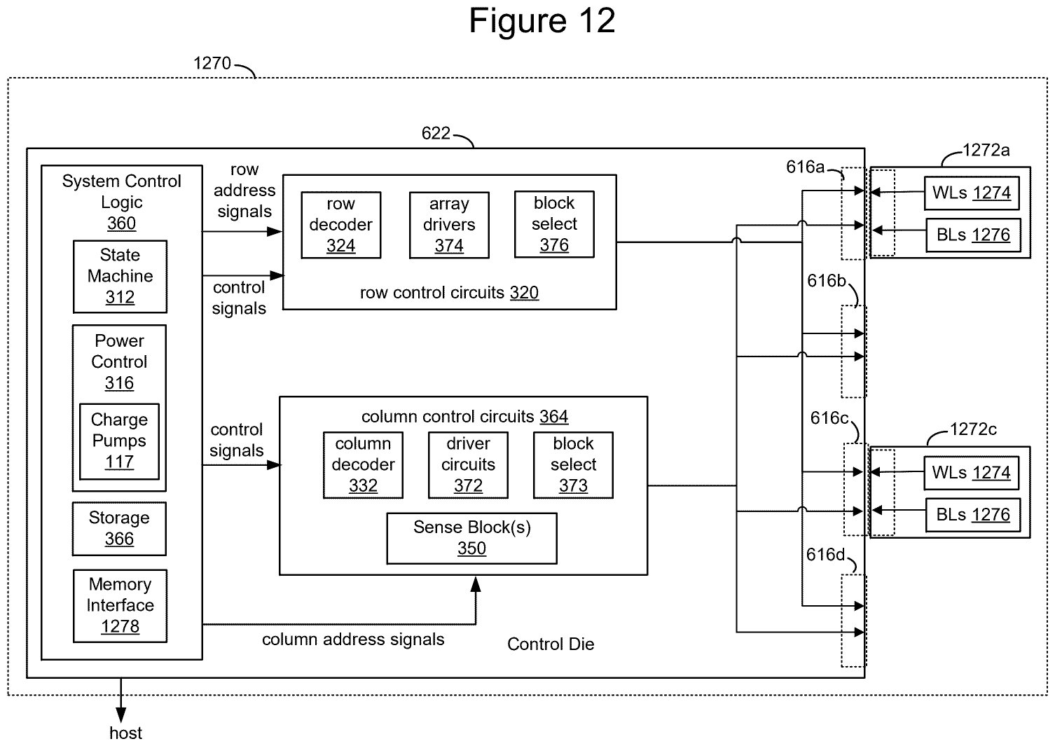

FIG. 12 illustrates an example of an integrated memory assembly 1270 formed by bonding two memory chiplets, 1272a and 1272c, to control die 622. Certain components of control die 622 were previously described with respect to control die 311 of integrated memory assembly 307 (FIG. 2B) and are not further described here.

In contrast to integrated memory assembly 307, integrated memory assembly 1270 includes two memory chiplets, 1272a and 1272c, that are connected to corresponding slots, 616a and 616c, of control die 622. Memory chiplets 1272a and 1272c each include word lines 1274 and bit lines 1276 and are aligned and bonded so that pads of memory chiplets 1272a and 1272c are bonded to corresponding pads of slots 616a and 616c to connect WLs 1274 to row control circuits 320 and connect BLs 1276 to column control circuits 364. Slots 616b and 616d are unused in integrated memory assembly 1270. System control logic 360 may include circuits to detect the presence/absence of memory chiplets at each of slots 616a-d and to configure operation accordingly. For example, memory interface circuit 1278 may be configured to detect presence/absence of memory chiplets at each slot 616a-d (and may perform additional detection, for example, of capacity and/or configuration of each memory chiplet). The physical configuration (number and types of memory chiplets) may be used to determine space available for data storage (e.g., to initiate logical-to-physical mapping). Memory access operations (e.g., write, read and erase operations) may be directed according to the configuration detected by memory interface circuit 1278 (e.g., accessing memory chiplets 1272a and 1272c through corresponding slots 616a and 616c without attempting access through slots 616b and 616d).

In some memory dies that include a 3D memory structure (e.g., memory structure 126), one or more staircase areas may be provided to facilitate connection of word lines in different word line layers. For example, staircase areas may be provided on either side of a memory array area to facilitate connection of word lines from two sides of a memory structure.

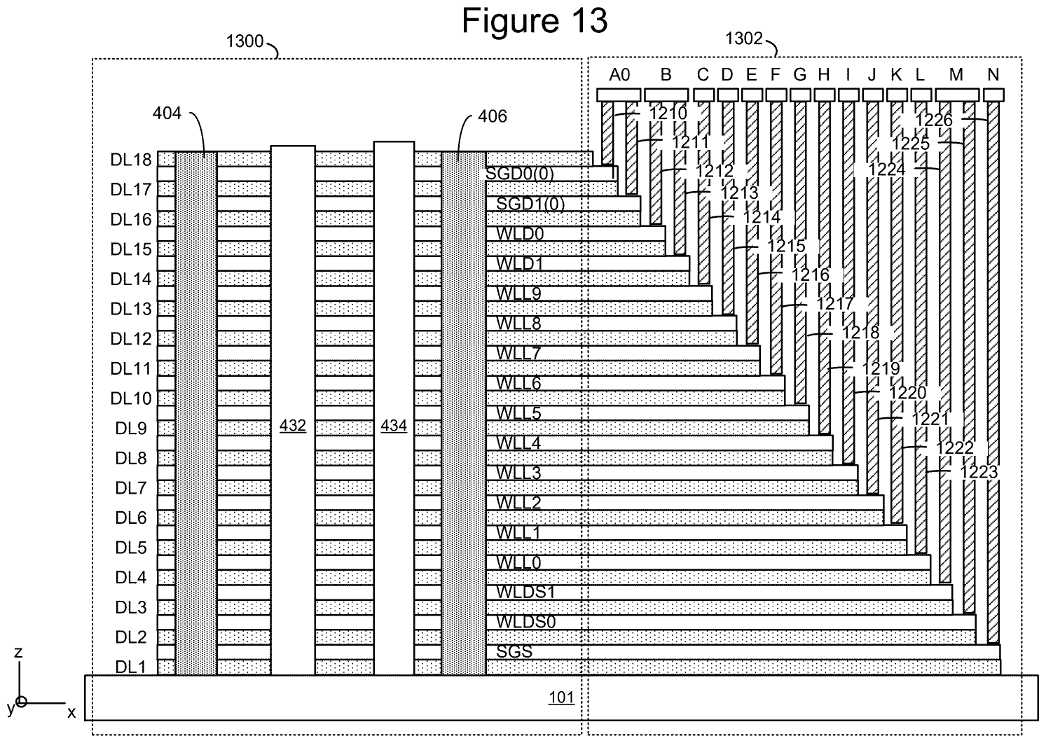

FIG. 13 shows an example of a staircase structure that includes terraced word line (control gate) layers and an example of connections to bond pads, where each word line layer is connected to a separate bond pad. In this example, the word line layers (along with select gate layers) form a terrace or staircase at one side of the block (a similar staircase may be formed on the opposite side of the structure). A vertical word line via is formed on an exposed top portion of each word line layer so that each word line is electrically connected to a corresponding vertical word line via. Each vertical word line via may extend to a metallization layer above the stack, where bond pads are formed on the vias. The vertical word line vias may comprise metal or other conductive material. The bond pads may be metal and may be connected to a row decoder to receive voltages for application to the word line layers. Each bond pad may be connected to one or more vias.

An array area 1300 is shown that includes memory cells formed at the intersection of vertical columns (e.g., column 432) or local bit lines with word lines (e.g., any of WLL0-WLL9). This structure may be similar to that of memory structure 126 as previously described.

In addition to array area 1300, FIG. 13 shows staircase area 1302, which includes a staircase structure in which a step corresponds to a word line layer (additional steps are provided for select gate layers). Bond pads A0-N are located at the tops of vertical word line vias to enable electrical connection. For example, bond pad N is connected to a via 1226 which in turn is connected to the SGS layer. Bond pad M is connected to vertical word line vias 1224 and 1225, respectively, which in turn are connected to the WLDS1 and WLDS0 layers (dummy word line layers), respectively. Bond pads C-L are connected to vertical word line vias 1214-1223, respectively, which in turn are connected to the WLL9-WLL0 layers, respectively. Bond pad B is connected to vertical word line vias 1212 and 1213, respectively, which in turn are connected to the WLD0 and WLD1 layers, respectively. Bond pad A0 is connected to vias 1210 and 1211, respectively, which in turn are connected to the SGD0(0) and SGD1(0) layers, respectively. SGD0(0) and SGD1(0) layers are used in SB0.

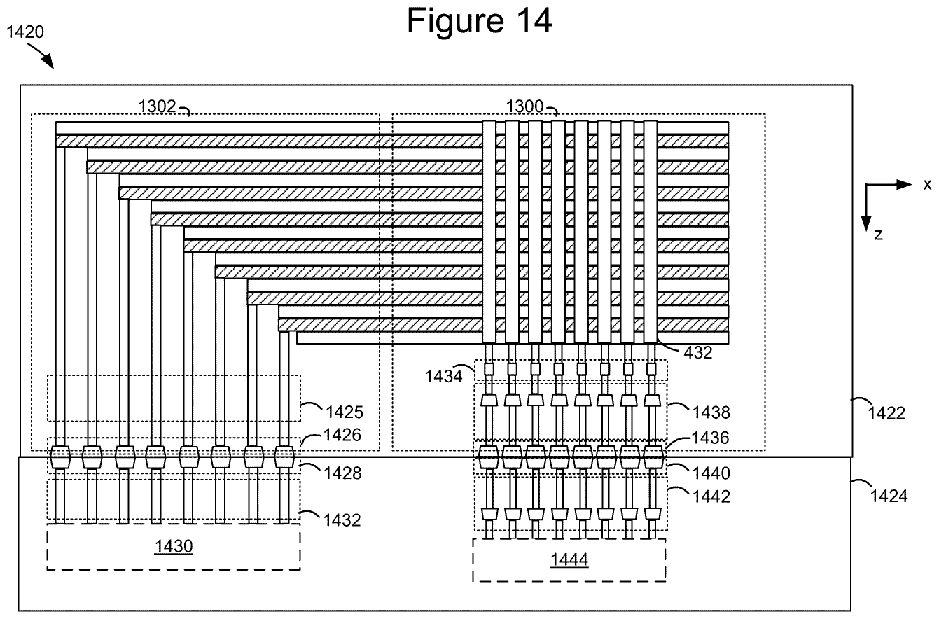

FIG. 14 illustrates an example of a portion of an integrated memory assembly 1420 that includes a memory die 1422 bonded to a control die 1424 including the arrangement of bond pads that couple word lines and bit lines in memory die 1422 to corresponding circuits in control die 1424. Memory die 1422 includes staircase area 1302 and array area 1300 as described with respect to FIG. 13. Conductive paths 1425 (e.g., vertical word line vias 1210-1226) in staircase area 1302 of memory die 1422 are connected to word line bond pads 1426 at a face of the memory die. Word line bond pads 1426 in turn are connected to word line bond pads 1428 on the control die 1424. Word line bond pads 1428 may be connected to circuitry 1430 (e.g., row control circuits 320, or word line switches/switching circuits) by conductive paths 1432. A space between the dies may be filled with an epoxy or other resin or polymer.

The NAND strings that include memory cells are connected by bit lines 1434. For example, a NAND string formed by vertical column 432 is connected to a bit line 1434. Bit lines 1434 in turn are connected to bit line bond pads 1436 by conductive paths 1438. Bit line bond pads 1436 are bonded to corresponding bit line bond pads 1440 of control die 1424, which are connected through conductive paths 1442 to control circuits 1444 (e.g., column control circuits 364, or bit line control circuits, including sense amplifiers and/or data latches, or “SADL”).

While FIG. 14 shows vertical connections from word lines in staircase area 1302, through vertical word line vias 1425, bond pads 1426 and 1428, and conductive paths 1432 to circuitry 1430 and vertical connections from bit lines 1434, through conductive paths 1438, bond pads 1436 and 1440 and conductive paths 1442 to control circuits 1444, in some examples, connections may be made differently.

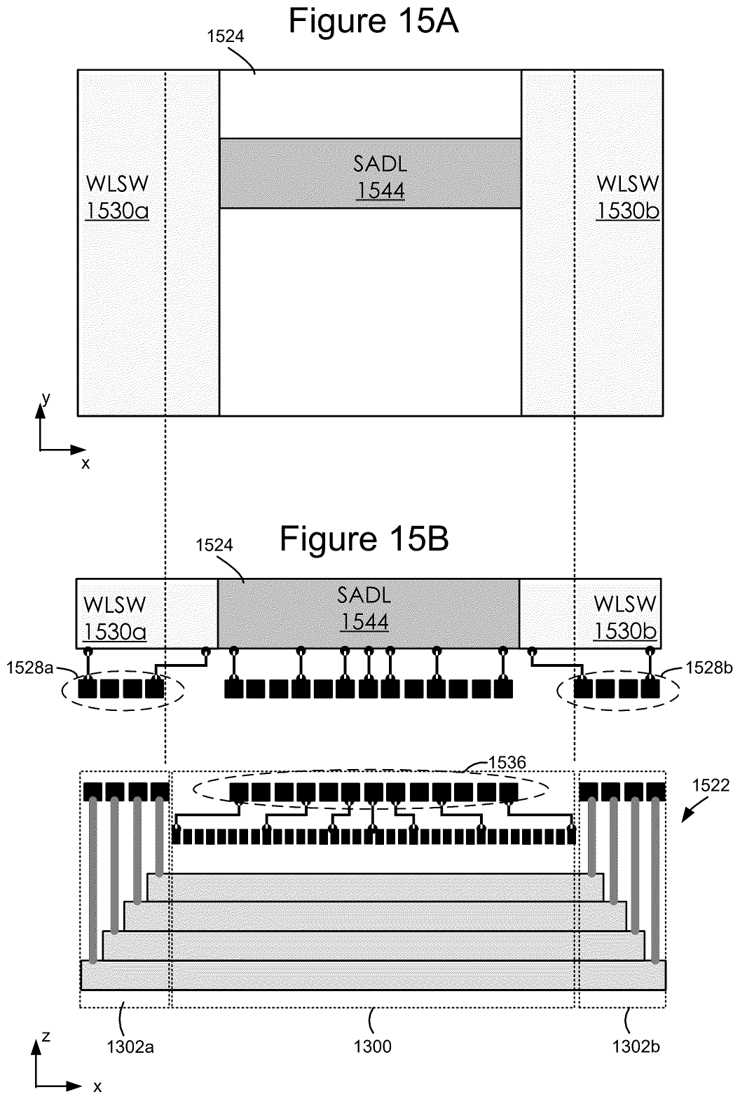

FIGS. 15A-B show an example in which circuits in a control die 1524 do not align directly with corresponding components in a memory die 1522. FIG. 15A shows the arrangement of control circuits including word line switches, WLSW 1530a and 1530b (e.g., row control circuits), and SADL 1544 (e.g., column control circuits) of control die 1524 in plan view. FIG. 15B shows a cross-sectional view of control die 1524 and memory die 1522 in cross-sectional view. Row control circuits such as word line switches WLSW 1530a and 1530b of control die 1524 may be larger than corresponding staircase areas 1302a and 1302b of memory die 1522 as shown. FIG. 15B shows that in memory die 1522, some bit line bond pads are not directly over corresponding bit lines (e.g., bit line bond pads 1536 occupy only a central portion of array area 1300 with traces that fan-out from bond pads 1536 to connect to bit lines). In control die 1524, word line bond pads 1528a and 1528b are connected to corresponding circuits, WLSW 1530a and 1530b, by traces that also fan-out.

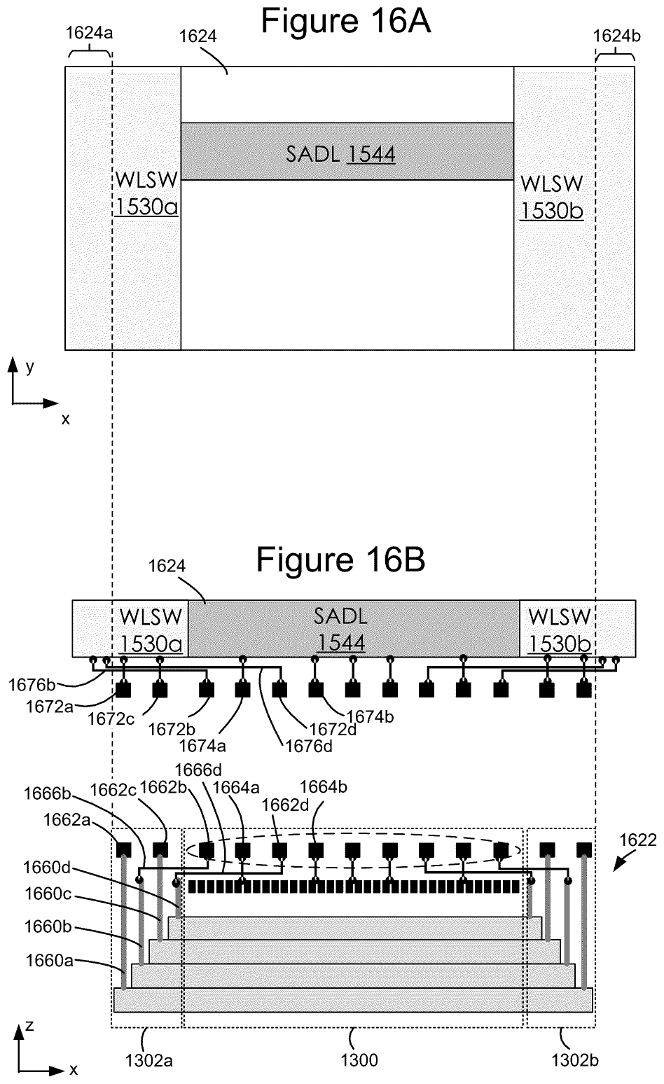

In contrast with FIGS. 15A-B, FIG. 16A-B show an example in which a control die 1624 is bonded with a memory die 1622 that has a different size (memory die or chiplet is smaller than control die). This results in a portions of control die 1624 extending beyond memory die 1622 to form overhang regions 1624a and 1624b. For example, using die-to-wafer bonding (or die-to-die bonding) to bond one or more memory chiplets to corresponding slot(s) of a control die in a control circuit wafer (or separate from such a wafer) may enable such a size difference. While aspects of the present technology are described with respect to die-to-wafer bonding, the present technology is not limited to such examples.

FIG. 16A shows the arrangement of control circuits including word line switches, WLSW 1530a and 1530b (e.g., row control circuits), and SADL 1544 (e.g., column control circuits) of control die 1524 in plan view. Overhang regions 1624a and 1624b extend beyond memory die 1622 in the x-direction and include portions of WLSW 1530a and 1530b. FIG. 16B shows a cross-sectional view of control die 1624 and memory die 1622. Row control circuits such as word line switches WLSW 1530a and 1530b of control die 1624 are not aligned with staircase areas 1302a and 1302b of memory die 1622. Unlike FIG. 15A, FIG. 16B shows that in memory die 1522, some word line bond pads are located in array area 1300 and are connected to vertical word line vias by horizontal traces that extend from staircase areas 1302a and 1302b to array area 1300. For example, while word line bond pad 1662a is directly above and electrically connected to via 1660a and word line bond pad 1662c is directly above and electrically connected to via 1660c, vertical word line vias 1660b and 1660d are not connected to word line bond pads that are directly above them. Vertical word line via 1660b is connected to word line bond pad 1662b in array area 1300 by trace 1666b and via 1660d is connected to word line bond pad 1662d in array area 1300 by trace 1666d. Traces 1666b and 1666d extend from staircase area 1302a into array area 1300 where they extend over, and at right angles to, bit lines.

Bit line bond pads of memory die 1622 are located in array area 1300 in this example. For example, FIG. 16B shows bit line bond pads 1664a-b. Bit line bond pad 1664a is located between word line bond pad 1662b and word line bond pad 1662d, with word line bond pad 1662d located between bit line bond pads 1664a and 1664b in an alternating WL/BL arrangement in array area 1300.

In control die 1624, word line bond pads 1672a and 1672c (which are bonded to corresponding word line bond pads 1662a and 1662c) in staircase area 1302a are connected to WLSW 1530a by vertical connections, while word line bond pads 1672b and 1672d (which are bonded to corresponding word line bond pads 1662b and 1662d) in array area 1300 are connected to WLSW 1530a by traces 1676b and 1676d respectively. Word line bond pads 1672b and 1672d and bit line bond pads 1674a and 1674b in array area are in an alternating arrangement corresponding to corresponding word line and bit line bond pads 1662b, 1662d, 1664a and 1664b of memory die 1622. While bond pads of a single memory die 1622 with a corresponding slot of control die 1624 are shown, additional memory dies may be similarly bonded to control die 1624.

Locating at least some word line bond pads in the array area may facilitate use of memory dies or chiplets that are smaller than a control die (e.g., facilitating overhangs and misalignment of staircase areas with corresponding control circuits such as WLSW 1530a-b). Such an arrangement may also facilitate use of larger bond pads (e.g., all word line bond pads do not have to be located in the staircase area) and may be suitable for die-to-wafer bonding (e.g., providing a greater margin for die-to-wafer misalignment). Traces that connect vertical word line vias in a staircase area with word line bond pads in an array area may be arranged in any suitable pattern. Word line and bit line bond pads in the array area may be arranged in any suitable pattern.

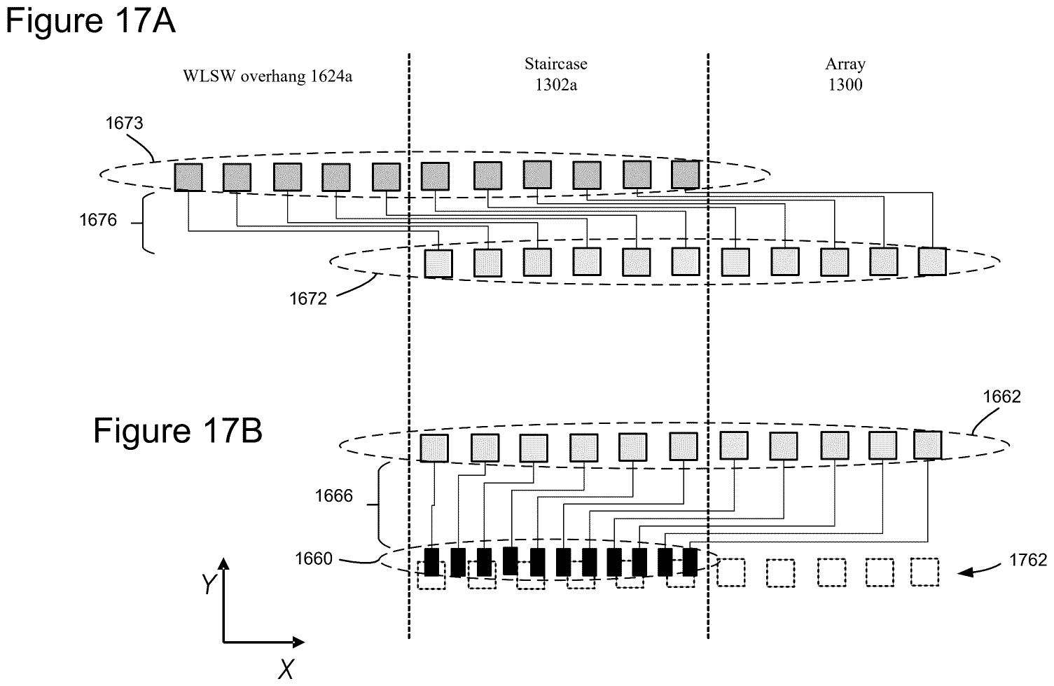

FIGS. 17A-C show examples of routing of traces in a control die (e.g., control die 1624) and a corresponding memory die (e.g., memory die 1622) respectively. FIG. 17A shows routing of traces 1676 (e.g., 1676d) in control die 1624. A row of word line bond pads 1672 (e.g., word line bond pads 1672a-d) extend across staircase area 1302a and into array area 1300. Word line bond pads 1672 are connected by traces 1676 to a row of WLSW connections 1673 located in staircase area 1302a and overhang region 1624a (locations of WLSW connections 1673 may correspond to location of WLSW circuits in control die 1624). Traces 1676 enable connection of WLSW circuits (including in overhang region 1624a) through bond pads located in staircase area 1302a and array area 1300.

FIG. 17B shows an example of routing of traces 1666 (e.g., traces 1666a and 1666d) in memory die 1622 to connect word line bond pads 1662, which are arranged for bonding with word line bond pads 1672. A row of vias 1660 (e.g., vertical word line vias 1660a-d) located in staircase area 1302a are connected by traces 1666 to a row of word line bond pads 1662 (e.g., word line bond pads 1662a-d) that extends across staircase area 1302a and into array area 1300. Traces 1666 may extend over and at right angles to bit lines (not shown) that extend in the y-direction. Traces 1666 may be considered an example of means for electrically connecting vertical word line vias to first word line bond pads located in the staircase area and to second word line bond pads that are located outside the staircase area (e.g., in array area 1300). It can be seen that the dimensions of the row of word line bond pads 1662 (pad dimensions and spacing) is greater than the dimensions of the row of vias 1660, which may facilitate alignment with word line bond pads 1672 (e.g., facilitate die to wafer alignment). FIG. 17B also shows another row of word line bond pads 1762 in outline. Row 1762 may extend over row 1660 and/or traces 1666 (e.g., word line bond pads may be displaced along the y-direction from the vias that they are connected to).

FIG. 17C shows another example of routing of traces 1666 (e.g., traces 1666a and 1666d) in memory die 1622. A row of vertical word line vias 1660 (e.g., vias 1660a-d) are located in staircase area 1302a as shown in FIG. 16B. Some (first) vertical word line vias are directly connected to bond pads (first bond pads) that lie directly over corresponding vias in staircase area 1302a. For example, via 1660a is directly connected to word line bond pad 1662a and via 1660c is directly connected to word line bond pad 1662c. Some (second) vertical word line vias are connected by traces to word line bond pads (second word line bond pads) that are laterally displaced from corresponding vias along the x-direction and are located in array area 1300 (e.g., traces extend across staircase area 1302a and into array area 1300). For example, vertical word line via 1660b is connected by trace 1666b to word line bond pad 1662b and vertical word line via 1660d is connected by trace 1666d to word line bond pad 1662d. The dimensions of the row of word line bond pads 1662 (pad dimensions and spacing) is greater than the dimensions of the vias of row 1660, which may facilitate alignment with word line bond pads 1672 (e.g., facilitate die to wafer alignment). Traces, such as traces 1666b and 1666d may extend over and at right angles to bit lines in array area 1300 (not shown in FIG. 17C).

In this example, first vias are directly connected to first bond pads in the staircase region and second vias are connected by traces to second bond pads in the array region (in other examples a different pattern may be applied). In this example, first and vias are interleaved in staircase area 1302a so that, for example, odd vias are directly connected and even vias are connected by traces (in other examples, a different pattern may be used). While first and second word line bond pads 1662 are aligned to form a row that extends through staircase area 1302a into array area 1300, other arrangements may be used. The pattern of traces shown includes traces on either side of row 1660 in an alternating arrangement. For example, trace 1666b extends from via 1660b in the positive y-direction (above row 1660 in FIG. 17C) while trace 1666d extends from via 1660d in the negative y-direction (below row 1660 in FIG. 17C). Other arrangements of traces may be implemented. The arrangement of FIG. 17C may be considered more efficient than the arrangement of FIG. 17B because some vias do not require traces, thereby reducing the number of traces needed, and traces extend on either side of a row of vias to use available space more efficiently. Traces such as traces 1666b and 1666d may be considered an example of means for electrically connecting the second plurality of vertical word line vias to second word line bond pads that are located outside the staircase area.

Bond pads (e.g., word line bond pads and/or bit line bond pads in any of the previous examples) may be arranged in any suitable pattern. The distance between bond pads, the “bond pitch”, for a given number of bond pads may depend on the arrangement of bond pads (e.g., some patterns may enable a larger spacing for a given number of bond pads in an area such as a staircase area and/or array area).

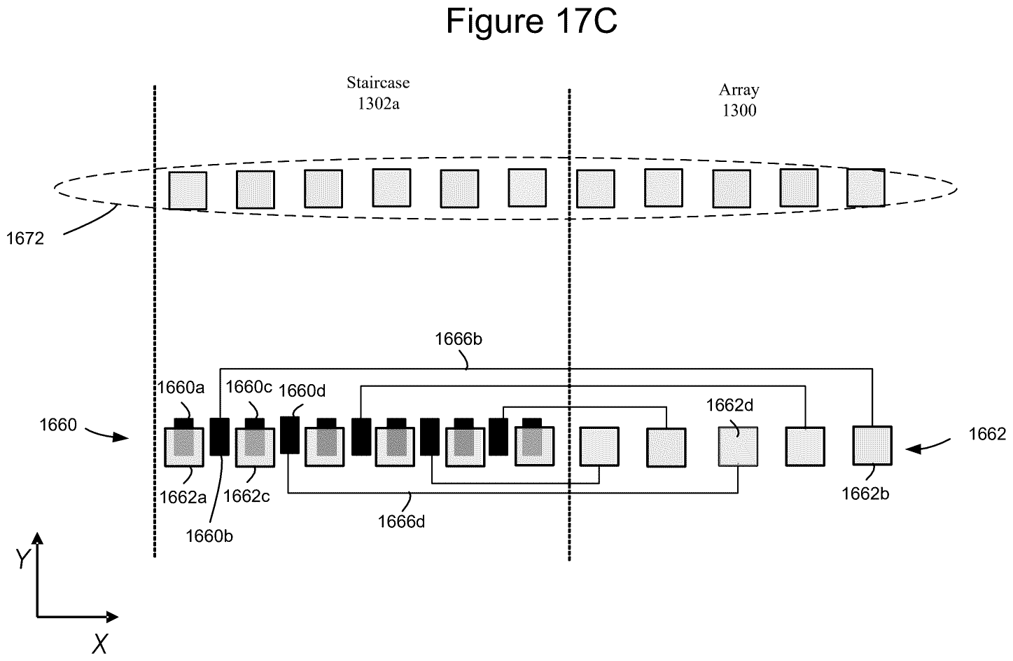

FIG. 18A shows a first example of an arrangement of bond pads 1880a-d. In this arrangement, bond pads 1880a-d are located at corners of a square so that each bond pad is displaced from its neighbors in the x-direction and the y-direction by the bond pitch (square pattern may be repeated so that bond pads are in a grid arrangement).

FIG. 18B shows a second example of an arrangement of bond pads 1880a-g. In this arrangement, bond pads 1880a-g are arranged in a hexagonal pattern, with a bond pad in the center of the hexagon and one bond pad at each corner of the hexagon. The length of each side of the hexagon is one bond pitch with the central bond pad 1800g equidistant from each bond pad 1880a-f at a distance of one bond pitch. This pattern, which is repeated in a honeycomb arrangement enables a more efficient use of available space (e.g., enabling more bond pads per unit area for a given bond pitch or enabling a greater bond pitch for a given number of bond pads per unit area). Word line bond pads in a staircase area (e.g., word line bond pads 1662a, 1662c in staircase area 1302a) may be arranged in a hexagonal pattern as shown to enable a greater number of bond pads to be located in the staircase area and/or enable a greater bond pitch. Word line bond pads and bit line bond pads in an array area (e.g., word line bond pads 1662b, 1662d and bit line bond pads 1664a, 1664b in array area 1300 in FIG. 16B) may be arranged in a repeating hexagonal pattern (e.g., the arrangement of FIG. 18B repeated across x-y plane) to enable a greater number of bond pads to located in the array area and/or enable a greater bond pitch.

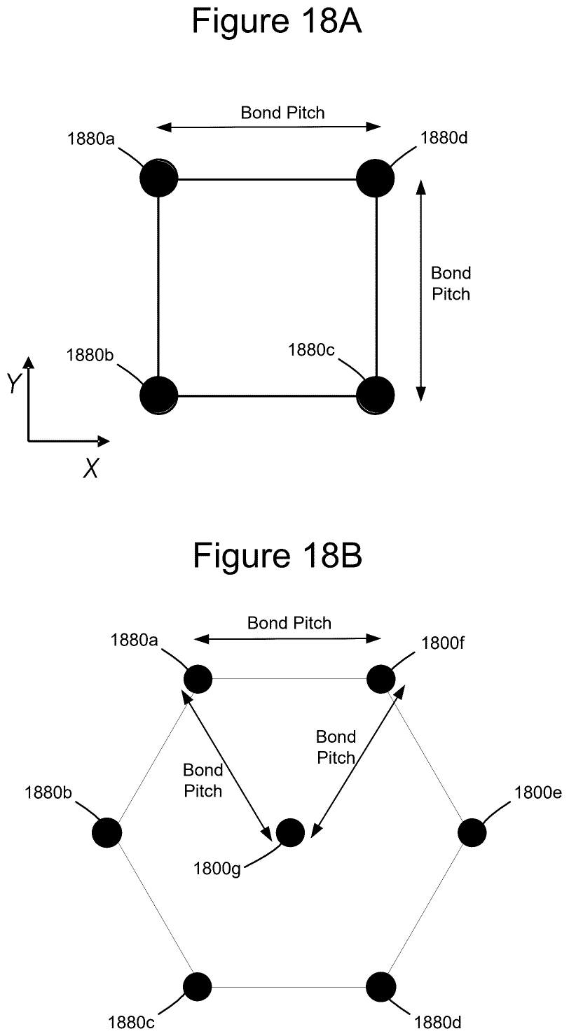

FIG. 19 shows an example of a method according to aspects of the present technology. The method includes forming a 3D nonvolatile memory structure having a memory array area and a staircase area in a memory die, the memory array area including a plurality of nonvolatile memory cells connected by word lines and bit lines, the staircase area including a plurality of steps contacted by vertical word line vias, each step corresponds to a word line layer that is connected to a corresponding via 1990 (e.g., forming a structure such as shown in FIG. 13). The method further includes forming a plurality of bond pads that includes word line bond pads that are electrically connected to the plurality of word lines and bit line bond pads that are electrically connected to the plurality of bit lines on a surface of the memory die, the plurality of bond pads formed such that a first plurality of the word line bond pads are located in the staircase area and a second plurality of the word line bond pads are located in the memory array area 1992 (e.g., word line bond pads 1662b and 1662d located in array area 1300).

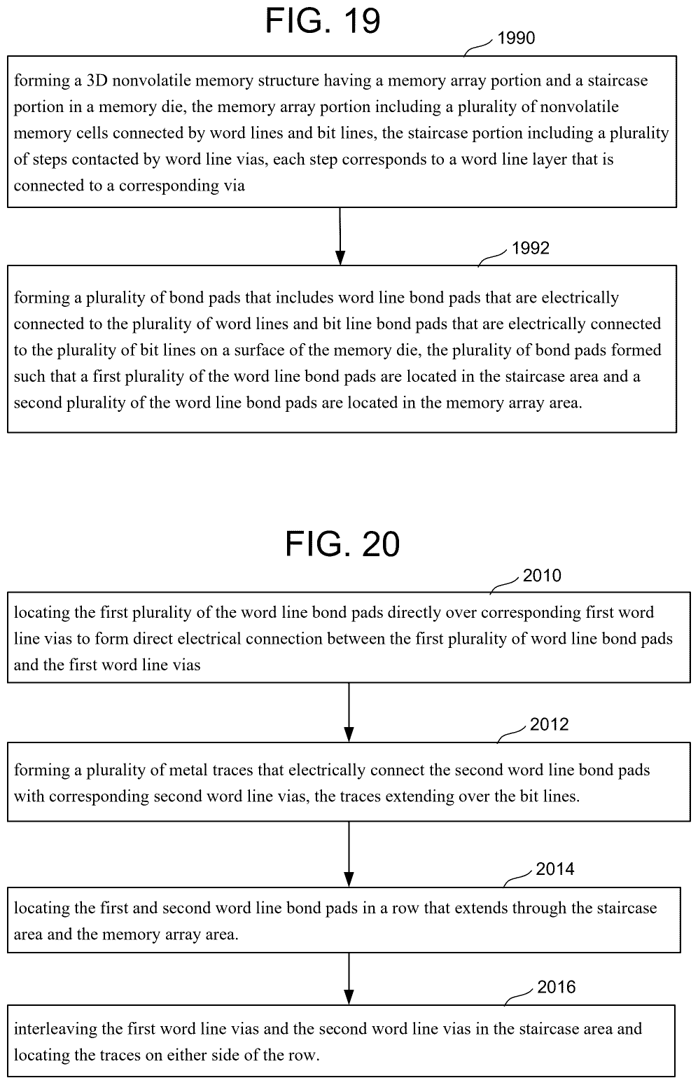

FIG. 20 shows an example of additional optional steps that may be combined with the method of FIG. 19. FIG. 20 includes locating the first plurality of the word line bond pads directly over corresponding first vertical word line vias to form direct electrical connection between the first plurality of word line bond pads and the first vertical word line vias 2010 (e.g., word line bond pads 1662a and 1662c located directly over corresponding vias 1660a and 1660c respectively), forming a plurality of metal traces that electrically connect the second word line bond pads with corresponding second vertical word line vias, the traces extending over the bit lines 2012 (e.g., traces 1666) and locating the first and second word line bond pads in a row that extends through the staircase area and the memory array area 2014 (e.g., row of bond pads 1662 extending through staircase area 1302a and array area 1300). The method optionally includes interleaving the first word line vias and the second word line vias in the staircase area and locating the traces on either side of the row 2016 (e.g., as shown in FIG. 17C).

An example of an apparatus includes a memory die having a 3D memory structure that includes nonvolatile memory cells in an array area. The nonvolatile memory cells are connected by word lines and bit lines. The word lines are connected to vertical word line vias in a staircase area adjacent to the array area. The vertical word line vias include a first plurality of vertical word line vias connected to first word line bond pads in the staircase area and a second plurality of vertical word line vias connected to second word line bond pads in the array area.

The apparatus may include a plurality of metal traces connecting the second plurality of vertical word line vias to the second word line bond pads, the plurality of metal traces extending over the bit lines in the array area. The apparatus may include a plurality of bit line bond pads located in the array area, each bit line bond pad electrically connected to a corresponding bit line. The first word line bond pads may be disposed in a honeycomb arrangement. The apparatus may include a control die that is bonded to the memory die such that each bit line bond pad, first word line bond pad and second word line bond pad is bonded to a corresponding control die bond pad. The control die may be larger than the memory die. The control die may be bonded to at least one additional memory die. Each of the first word line bond pads may be directly over a corresponding via of the first plurality of vertical word line vias in the staircase area and the second word line bond pads may be laterally displaced from the second plurality of vertical word line vias and connected to the second plurality of vertical word line vias by traces that extend into the array area above and at right angles to the bit lines. The first word line bond pads and the second word line bond pads may be aligned to form a row that extends through the staircase area and the memory array area. The first vertical word line vias and the second vertical word line vias may be interleaved in the staircase area and the traces extend from the second vertical word line vias on either side of the row.

An example of a method includes forming a 3D nonvolatile memory structure having a memory array area and a staircase area in a memory die, the memory array area including a plurality of nonvolatile memory cells connected by a plurality of word lines and a plurality of bit lines, the staircase area including a plurality of steps contacted by vertical word line vias, each step corresponds to a word line layer that is connected to a corresponding vertical word line via; and forming bond pads including word line bond pads that are electrically connected to the plurality of word lines and bit line bond pads that are electrically connected to the plurality of bit lines on a surface of the memory die, the bond pads formed such that a first plurality of word line bond pads are located in the staircase area and a second plurality of the word line bond pads are located in the memory array area.

The method may further include locating the first plurality of word line bond pads directly over corresponding first vertical word line vias to form direct electrical connection between the first plurality of word line bond pads and the first vertical word line vias; and forming a plurality of metal traces that electrically connect the second word line bond pads with corresponding second vertical word line vias, the traces extending over the bit lines. The method may further include locating the first and second word line bond pads in a row that extends through the staircase area and the memory array area. The method may further include interleaving the first vertical word line vias and the second vertical word line vias in the staircase area and locating the plurality of metal traces on either side of the row. The method may further include aligning a control die with the memory die such that the word line bond pads and the bit line bond pads are aligned with corresponding control die bond pads on a surface of the control die; and bonding the word line bond pads and the bit line bond pad of the memory die with the corresponding control die bond pads on the surface of the control die. The method may further include subsequently aligning and bonding at least one additional memory die with the control die. Forming the plurality of bond pads may include locating the plurality of bond pads in a honeycomb arrangement.

An example of a memory system includes a control circuit die having a plurality of slots for bonding of memory dies; and a plurality of memory dies bonded to corresponding slot of the control circuit die, each memory die having a 3D memory structure that includes nonvolatile memory cells in an array area, the nonvolatile memory cells connected by word lines and bit lines, the word lines connected to vertical word line vias in a staircase area adjacent to the array area, a first plurality of the vertical word line vias connected to first word line bond pads in the staircase area, each memory die further including means for electrically connecting a second plurality of vertical word line vias to second word line bond pads that are located outside the staircase area.

The second word line bond pads may be located in the array area with a plurality of bit line bond pads, the second word line bond pads and the plurality of bit line bond pads arranged in a repeating hexagonal pattern. The first and second word line bond pads may be aligned in a row.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
a memory die having a 3D memory structure that includes nonvolatile memory cells in an array area, the nonvolatile memory cells connected by word lines and bit lines, the word lines connected to vertical word line vias in a staircase area adjacent to the array area, the vertical word line vias including a first plurality of vertical word line vias connected to first word line bond pads in the staircase area and a second plurality of vertical word line vias connected to second word line bond pads in the array area.

2. The apparatus of claim 1, further comprising a plurality of metal traces connecting the second plurality of vertical word line vias to the second word line bond pads, the plurality of metal traces extending over the bit lines in the array area.

3. The apparatus of claim 2, further comprising a plurality of bit line bond pads located in the array area, each bit line bond pad electrically connected to a corresponding bit line.

4. The apparatus of claim 3, wherein the first word line bond pads are disposed in a honeycomb arrangement.

5. The apparatus of claim 3, further comprising a control die that is bonded to the memory die such that each bit line bond pad, first word line bond pad and second word line bond pad is bonded to a corresponding control die bond pad.

6. The apparatus of claim 5, wherein the control die is larger than the memory die.

7. The apparatus of claim 6, wherein the control die is bonded to at least one additional memory die.

8. The apparatus of claim 1, wherein each of the first word line bond pads is directly over a corresponding via of the first plurality of vertical word line vias in the staircase area and the second word line bond pads are laterally displaced from the second plurality of vertical word line vias and are connected to the second plurality of vertical word line vias by traces that extend into the array area above and at right angles to the bit lines.

9. The apparatus of claim 8, wherein the first word line bond pads and the second word line bond pads are aligned to form a row that extends through the staircase area and the memory array area.

10. The apparatus of claim 9, wherein first vertical word line vias and the second vertical word line vias are interleaved in the staircase area and the traces extend from the second vertical word line vias on either side of the row.

11. A method comprising:
forming a 3D nonvolatile memory structure having a memory array area and a staircase area in a memory die, the memory array area including a plurality of nonvolatile memory cells connected by a plurality of word lines and a plurality of bit lines, the staircase area including a plurality of steps contacted by vertical word line vias, each step corresponds to a word line layer that is connected to a corresponding vertical word line via; and
forming bond pads including word line bond pads that are electrically connected to the plurality of word lines and bit line bond pads that are electrically connected to the plurality of bit lines on a surface of the memory die, the bond pads formed such that a first plurality of word line bond pads are located in the staircase area and a second plurality of the word line bond pads are located in the memory array area.

12. The method of claim 11, further comprising:
locating the first plurality of word line bond pads directly over corresponding first vertical word line vias to form direct electrical connection between the first plurality of word line bond pads and the first vertical word line vias; and
forming a plurality of metal traces that electrically connect the second word line bond pads with corresponding second vertical word line vias, the traces extending over the bit lines.

13. The method of claim 12, further comprising:
locating the first and second word line bond pads in a row that extends through the staircase area and the memory array area.

14. The method of claim 13, further comprising:
interleaving the first vertical word line vias and the second vertical word line vias in the staircase area and locating the plurality of metal traces on either side of the row.

15. The method of claim 11, further comprising:
aligning a control die with the memory die such that the word line bond pads and the bit line bond pads are aligned with corresponding control die bond pads on a surface of the control die; and
bonding the word line bond pads and the bit line bond pads of the memory die with the corresponding control die bond pads on the surface of the control die.

16. The method of claim 15, further comprising:
subsequently aligning and bonding at least one additional memory die with the control die.

17. The method of claim 11, wherein forming the plurality of bond pads includes locating the plurality of bond pads in a honeycomb arrangement.

18. A memory system comprising:
a control circuit die having a plurality of slots for bonding of memory dies; and
a plurality of memory dies bonded to corresponding slot of the control circuit die, each memory die having a 3D memory structure that includes nonvolatile memory cells in an array area, the nonvolatile memory cells connected by word lines and bit lines, the word lines connected to vertical word line vias in a staircase area adjacent to the array area, a first plurality of the vertical word line vias connected to first word line bond pads in the staircase area, each memory die further including means for electrically connecting a second plurality of vertical word line vias to second word line bond pads that are located outside the staircase area.

19. The memory system of claim 18 wherein the second word line bond pads are located in the array area with a plurality of bit line bond pads, the second word line bond pads and the plurality of bit line bond pads arranged in a repeating hexagonal pattern.

20. The memory system of claim 18, wherein the first and second word line bond pads are aligned in a row.
